(19) United States
(12) Patent Application Publication
(10) Pub. No.: US 2011/0061898 A1
(43) Pub. Date: Mar. 17, 2011

(54) REDUCING CROSS-TALK IN HIGH SPEED CERAMIC PACKAGES USING SELECTIVELY-WIDENED MESH

(75) Inventors: Bhyrav Mutnury, Austin, TX (US); Jinwoo Choi, Austin, TX (US); Moises Cases, Austin, TX (US); Nanju Na, Essex Junction, VT (US)

(73) Assignee: INTERNATIONAL BUSINESS MACHINES CORPORATION, Armonk, NY (US)

(21) Appl. No.: 12/560,133

(22) Filed: Sep. 15, 2009

(51) Int. Cl. H05K 1/00; G06F 17/50; H05K 3/00

(52) U.S. Cl. 174/250; 29/846; 716/115

(57) ABSTRACT

One embodiment of the invention provides a multi-layered ceramic package. The ceramic package includes a signal layer having a plurality of signal lines and a mesh reference layer parallel to the signal layer. The mesh reference layer includes a plurality of intersecting reference lines of varying reference-line width in the plane of the mesh layer. The mesh reference lines may be widened in locations of probable signal cross-talk. Other embodiments of the invention include software for optimizing a ceramic package design by selectively widening mesh lines in regions of probable cross-talk, and systems for designing and manufacturing such a ceramic package.

### BACKGROUND

1. Field of the Invention

The present invention relates to integrated circuits, and more specifically to multi-layered ceramic packages.

2. Background of the Related Art

An integrated circuit (IC), also commonly referred to as a “microchip” or “chip,” is an electronic circuit comprising miniaturized semiconductor devices formed in a semiconductor substrate. Many copies of a chip may be formed on a large semiconductor wafer and then cut into individual chips, which may be interchangeably referred to in the art as “die chips” or simply “dies.” Semiconductor materials such as silicon are brittle, so an individual die chip is commonly packaged on a carrier to form a chip carrier, also known as a “chip package” or simply “package.” The carrier protects the fragile chip, in addition to providing an electrical and mechanical interface between the chip and a printed circuit board (PCB).

A ceramic package is a type of package popular in a wide range of applications due to its excellent reliability and the ability to carry a large number of signal lines. A ceramic package is usually composed of multiple layers. For example, a multilayer ceramic package may be formed by stacking and laminating unfired ceramic layers and firing the laminated structure. The wiring layers in a multi-layer ceramic package may each be sandwiched between upper and lower (e.g. ground and voltage) reference layers. A reference layer typically comprises a grid structure with intersecting reference lines, which may be accessed by vias.

Noise coupling between the signal lines of a package has become a growing concern as signal speeds and the number of signal lines in a chip package increase. An increase in both signal speeds and the proximity of signal lines has increased the potential for undesirable cross-talk between the signal lines in the same signal layer or in adjacent signal layers. Cross-talk is caused primarily by inductive interaction between two adjacent signal lines in a multi-layered metallization scheme of an integrated circuit. Cross-talk limits the maximum signaling rates and performance in a chip package.

### BRIEF SUMMARY

One embodiment of the present invention provides a multi-layered ceramic package. The ceramic package includes a ceramic substrate, a signal layer having a plurality of signal lines in the ceramic substrate, and a mesh reference layer parallel to the signal layer. The mesh reference layer includes a plurality of intersecting reference lines of varying reference-line width in the plane of the mesh reference layer. In one example embodiment, the reference lines may be selectively widened only in regions having an increased probability of cross-talk, without compromising the bonding between layers and the resultant structural integrity. The method may be implemented by a computer program product including computer usable program code embodied on a computer usable storage medium for optimizing a multi-layer ceramic package.

Another embodiment of the invention provides a system for fabricating a multi-layered ceramic package. The system includes a multi-layered ceramic package design system configured to provide a multi-layered ceramic package design that includes a signal layer having a plurality of signal lines and a mesh reference layer parallel to the signal layer and having a plurality of reference lines. A mesh optimization engine included with the system is configured to identify a region of probable signal cross-talk in the signal layer of the multi-layered ceramic package design and selectively increase the width of reference lines in the region of probable signal cross-talk. A ceramic package fabrication system included with the system fabricates the multi-layered ceramic package based on the shielded multi-layered ceramic package design.

### BRIEF DESCRIPTION OF THE SEVERAL VIEWS OF THE DRAWINGS

FIG. 1 is a perspective view of a portion of a multi-layered ceramic package that may be optimized to reduce signal cross-talk according to an embodiment of the invention.

FIG. 2 is a schematic plan view of a region of the ceramic package prior to optimization.

FIG. 3 is a schematic plan view of the same region of the ceramic package as in FIG. 2, wherein the reference lines have been widened to reduce cross-talk.

FIG. 4 is a graph comparing near end noise waveforms on the victim signal line S5 due to all aggressor signal lines before and after selectively widening the mesh.

FIG. 5 is a graph showing far end (FE) noise waveforms on the victim signal line S5 due to all aggressor signal lines for the model before and after selectively widening the mesh.

FIG. 6 is a schematic plan view of an example mesh reference layer including two mesh regions having different mesh reference line widths.

FIG. 7 is a schematic plan view of an example mesh reference layer, wherein longitudinal mesh reference lines have a smooth, curved transition.

FIG. 8 is a schematic plan view of the mesh reference layer of FIG. 7, wherein the longitudinal mesh reference lines have a stepped, ninety-degree transition.

FIG. 9 is an exemplary block diagram of a system for fabricating a multi-layered ceramic package.

FIG. 10 is a flowchart outlining a method of optimizing a multi-layered ceramic package.

### DETAILED DESCRIPTION

Embodiments of the invention include a multi-layered ceramic package, wherein the mesh reference lines in a mesh reference layer are selectively widened in areas having the greatest potential for signal cross-talk. As a result, cross-talk is effectively reduced in selected regions having a higher probability of cross-talk, without compromising the overall structural integrity of the entire ceramic package. In one embodiment, the mesh reference layers in a multi-layered ceramic package are alternating positive and ground reference layers, with signal layers sandwiched between the reference layers. Signal lines in the signal layer are aligned with the mesh reference lines, except where the signal lines traverse an opening between intersecting longitudinal and lateral mesh reference lines. Vias are used to tie in signal lines with selected mesh reference lines in vertically-spaced reference layers or signal lines in other signal layers. The reference lines are widened subject to the constraints of an overall metal coverage limit imposed on a reference layer.

Other embodiments include a software embodiment for designing a ceramic package having selectively-widened mesh, and a system for designing and fabricating such a multi-layered ceramic package. The software may be used to optimize an existing ceramic package design, or to perform iterative optimization of a ceramic package. The system, which may incorporate the software, includes a multi-layered ceramic package design system configured to design a multi-layered ceramic package. The multi-layered ceramic package design includes a signal layer having a plurality of signal lines and a mesh reference layer that is parallel to the signal layer and has a plurality of reference lines. A mesh optimization engine is configured to identify a region of probable signal cross-talk in the signal layer of the multi-layered ceramic package design and selectively increase the width of reference lines in the region of probable signal cross-talk. The ceramic package may then be automatically fabricated using a fabrication system based on the shielded multi-layered ceramic package design.

Embodiments of the invention are discussed largely in the context of mesh having an orthogonal wiring pattern, including longitudinal and lateral mesh reference lines that intersect at ninety degrees to form rectangular openings therebetween. However, one skilled in the art having the benefit of this disclosure will appreciate that other mesh configurations may be optimized according to an embodiment of the invention. For example, another embodiment may include selectively widening the reference lines of a diagonal wiring pattern. Regardless of the direction of the mesh, the mesh reference lines may also be individually optimized by selectively widening individual mesh reference lines. Alternatively, entire regions of a mesh reference layer may be identified, wherein the width of the reference lines in particular regions are increased, so that the width of a particular mesh reference line varies from one region to the next. Widening the mesh reference lines helps reduce cross-talk between signal lines in different layers and even between signal lines in the same layer.

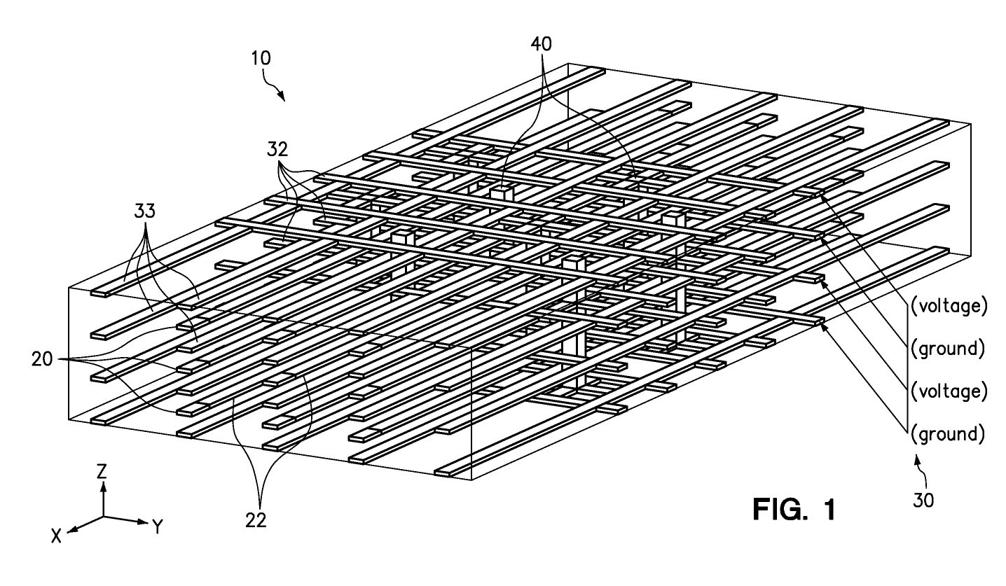

FIG. 1 is a perspective view of a portion of a multi-layered ceramic package 10 that may be optimized to reduce signal cross-talk according to an embodiment of the invention. In FIG. 1, the ceramic substrate material is shown as transparent for the purpose of illustrating reference lines and signal lines formed in the ceramic package. Electrically-conductive signal layers, generally indicated at 20, are sandwiched between metal mesh reference layers generally indicated at 30 within a ceramic substrate. The signal layers 20 and mesh reference layers 30 are generally planar layers that are parallel to one another and also parallel to an XY plane of a 3-axis (X, Y, Z) coordinate system indicated in FIG. 1. As such, the reference layers may be alternatively referred to as reference planes. The signal layers 20 include signal lines 22 (individually labeled S1-S9) formed in a ceramic substrate. The signal lines 22, alternatively referred to as signal nets or interconnects, are used to route signals and power between integrated circuit components throughout the ceramic package 10. The mesh reference layers 30 are alternating voltage reference layers and ground reference layers. Each mesh reference layer 30 includes a plurality of lateral mesh reference lines 32 intersecting at right angles with a plurality of longitudinal 33 mesh reference lines.

The mesh structure of intersecting lateral and longitudinal mesh reference lines 32, 33 provides a source of voltage (in voltage reference layers) or ground (in ground reference layers) to locations throughout the ceramic package 10. Selected reference lines 32, 33 in selected reference layers 30 are accessed by vias 40. The alternating signal layers 20 and reference layers 30 are stacked in the z-direction. The vias 40 extend in the z-direction from at least one signal layer 20 to at least one mesh reference layer 30. To connect to ground or voltage, structures known in the art, such as “x-hatch” structures (not shown), extend horizontally from one of the vias 40 to a selected reference line 32 within either a ground reference layer or a voltage reference layer 30.

Potential for cross-talk exists between signal lines 22 within a particular signal layer 20 or in adjacent signal layers 20 due to inductive and/or capacitive coupling. The probability of cross-talk is particularly high between two signal lines 22 in close proximity (e.g. within 60 μm apart) or at higher signal speeds (e.g. more than 2 gigabits per second). As edge rates and bus signaling speeds increase, signal lines 22 interact with other signal lines 22 on the same signal layer 20 or other signal layers 20 above and below. This cross-talk interaction between high speed signals introduces inter-symbol interference (ISI) on the signal lines 22 that severely limits the maximum signaling rates and performance on these signal lines. According to various embodiments of the invention, the width of the mesh reference lines 32 may be selectively varied to reduce the potential for cross-talk between signal lines 22. In particular, the width of mesh reference lines 32, 33 may be selectively increased in regions of probable signal cross-talk in the signal layers 20 of the ceramic package 10. In one aspect, regions wherein signal lines 22 are particularly sensitive to cross-talk may be identified, and the width of the mesh reference lines 32, 33 may be widened in those regions to reduce the magnitude of cross-talk that would otherwise occur. These regions that are particularly sensitive to cross-talk may be identified according to proximity, signal speed, or a combination thereof, which may be determined automatically by a computer using software described below and/or manually by a software user viewing a multichip module (MCM) file.

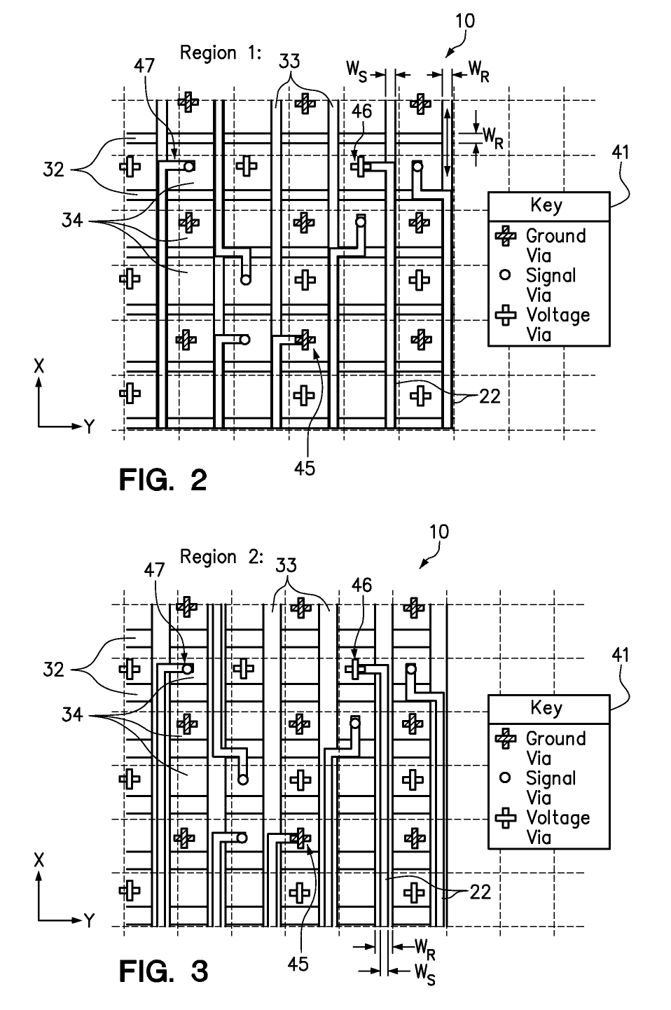

FIG. 2 is a schematic plan view (facing the XY plane) of a region of the ceramic package 10 selected for widening the reference lines in regions having a higher probability of cross-talk, such as regions having signal speeds greater than 2 gigabits through signal lines spaced within 60 μm apart. The ceramic package 10 has reference lines 32, 33 in the mesh reference layers 30. Rectangular openings 34 are defined between the mesh of lateral reference lines 32 and longitudinal reference lines 33. Ground vias, voltage vias, and signal vias, as individually identified by symbols indicated in the key 41, are centered within the openings 34. The ground vias may be used to tie signal lines 22 into ground reference layers. The voltage vias are used to tie signal lines 22 into voltage reference layers. The signal vias are used to tie the signal line 22 in one signal layer to a signal line 22 in another signal layer. For example, one of the signal lines 22 is shown tied into a ground via at 45. Another signal line 22 is tied into a voltage via at 46. Another signal line 22 is shown tied into a signal via at 47.

The path of each signal line 22 is aligned (relative to the XY plane) along its length with at least one of the lateral and longitudinal mesh reference lines 32, 33, except at locations where the signal lines 22 traverse openings 34 to tie into the vias 40. Although not required, the lateral reference lines 32 and the longitudinal reference lines 33 have the same reference-line width, W_{R}, which helps ensure symmetry to maintain mechanical strength without warping. The length, L, of a portion of a reference line is generally indicated. Within the region of the ceramic package 10 shown in FIG. 2, the signal lines 22 have a width, W_{S}, that is only slightly less than, but nearly the same width as the reference-line width W_{R} of the reference lines 32, 33. In one example, W_{R} is 66 μm while W_{S} is 55 μm.

FIG. 3 is a schematic plan view (also facing the XY plane) of the same region of the ceramic package 10 as in FIG. 2, wherein the reference lines 32, 33 have been widened according to an embodiment of the invention to reduce cross-talk. The path of each signal line 22 remains aligned with (and optionally centered above) the mesh reference lines 32, 33, except at locations where the signal lines 22 traverse an opening 34 to tie into one of the vias 40. The width W_{S} of the signal lines 22 is the same as in FIG. 3, while the lateral and longitudinal reference lines 32, 33 have been widened, which correspondingly reduces the size of the openings 34. Generally, it is desirable to widen reference lines such that the widened portion is at least 10% wider than the aligned one of the reference lines. In the particular embodiment of FIG. 3, the reference lines 32, 33 have been widened to a reference-line width W_{R} of 100 μm. The signal lines 22 within a particular signal layer and in adjacent layers are better shielded by virtue of the wider mesh reference lines.

The ceramic package 10 was modeled to evaluate the reduction of cross-talk as a result of widening the mesh reference lines 32, 33 from the reference-line width of 66 μm in FIG. 2 to the reference-line width 100 μm of FIG. 3. A full wave solver application was used to model a ceramic package and simulate the response of the ceramic package using both the reference-line width of FIG. 2 and the widened reference-line width of FIG. 3. The width for the signal lines was set to 55 μm for each simulation. Then, the model was run for each of the reference-line widths, in a software application known as the SPICE simulator, to compare cross-talk. In the model, a 1V ramp source was applied to inputs of signal line S1, S2, S3, S4, S6, S7, S8, and S9 (see FIG. 1). The signal line S5 was chosen as a victim signal line in this case. The inputs and outputs of these signal lines were terminated with 50 ohm resistors.

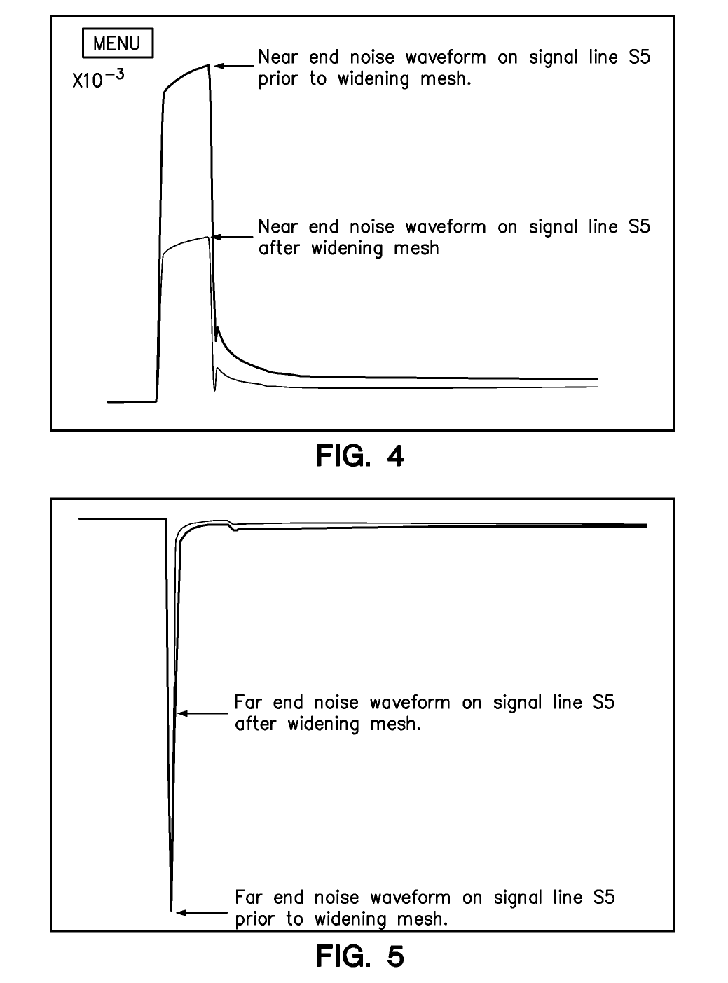

FIG. 4 is a graph comparing near end noise waveforms on the victim signal line S5 due to all aggressor signal lines before widening the mesh (FIG. 2) and after widening the mesh (FIG. 3). The graph demonstrates that the maximum near end noise voltage is greatly reduced by widening the mesh. In particular, an approximately 58% reduction was achieved by widening the mesh reference lines from 66 to 100 μm. This is because the widened mesh blocks more electric field and magnetic field between signal lines, which reduces mutual capacitance and mutual inductance between the signal lines. The reduction in mutual capacitance and inductance ultimately reduces cross-talk between the signal lines 22.

FIG. 5 is a graph comparing far end noise waveforms on the victim signal line S5 due to all aggressor signal lines before widening the mesh (FIG. 2) and after widening the mesh (FIG. 3). The graph also demonstrates that the maximum far end noise voltage is reduced greatly by widening the mesh. In particular, an approximately 53% reduction was achieved by widening the mesh reference lines from 66 μm (FIG. 2) to 100 μm (FIG. 3).

The overall metal coverage on a layer in manufacturing may be limited by manufacturing constraints. The metal coverage limit refers to the total area of a layer that may be occupied by metal. For example, the limit for metal coverage is typically 40% for a 7 mil layer. A metal coverage limit of 40% means that no more than 40% of the area of a particular layer be occupied by metal. Exceeding this metal coverage limit can reduce the bonding strength between layers due to reduced ceramic surface area. Thus, complying with this limit ensures bonding stability between layers. Thus, the mesh reference lines in a particular layer should be widened only to the extent that the metal coverage limit is not exceeded. In one embodiment, the mesh reference lines are widened only in the vicinity of higher-speed signal lines, rather than to uniformly widen the reference lines throughout a particular layer. Using this approach, the regions of a reference layer having potentially higher risk for cross-talk may be targeted, without exceeding the metal coverage limit.

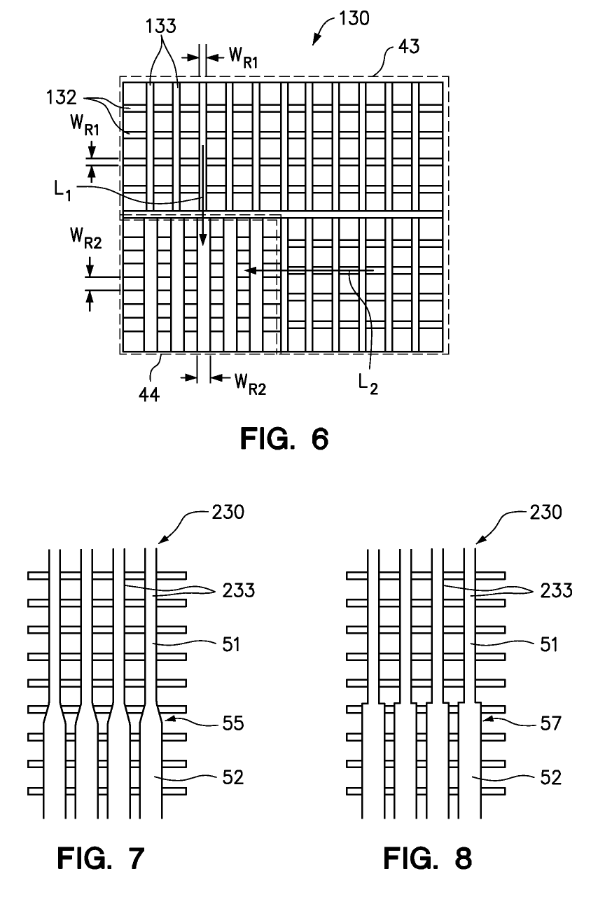

FIG. 6 is a schematic plan view of an example mesh reference layer 130 including first and second mesh regions 43, 44 having different mesh reference line widths. In the first mesh region 43, the lateral and longitudinal reference lines 132, 133 have a reference-line width of W_{R1}. In the second mesh region 44, the width of the lateral and longitudinal reference lines 132, 133 has been widened to W_{R2}, such that W_{R2} is greater than W_{R1}. The reference lines 132, 133 have been widened in the second mesh region 44 without breaking continuity of the reference lines 132, 133. Rather, lateral mesh reference lines 132 extend continuously from the first mesh region 43 to the second mesh region 44, and longitudinal mesh reference lines 133 also extend continuously from the first mesh region 43 to the second mesh region 44. Thus, the reference-line width W_{R1} of the lateral mesh reference lines 132 that cross over from the first mesh region 43 into the second mesh regions 44 varies along the length L₁. Likewise, the longitudinal mesh reference lines 133 that cross over from the first mesh region 43 into the second mesh region 44 varies along the length L₂.

Regions of widened mesh, such as the second mesh region 43, may be located throughout the reference layer 130, only a small portion of which is shown in FIG. 6. Regions having widened mesh lines may be located throughout the reference layer 130. Regions having widened mesh lines need not be all the same size. In a simple example, a mesh reference layer may include a first mesh region having standard-width mesh lines of 66 μm, a second mesh region having widened mesh lines of 80 μm, and a third mesh region having further-widened mesh lines of 100 μm. Furthermore, a widened reference line may follow a high-speed signal line across the package from point-to-point, such that the widened reference lines are selectively used throughout the package without being limited to a definable region.

Mesh lines can have a variety of different transitions from a narrower-mesh region to a wider-mesh region. For example, FIG. 7 is a schematic plan view of an example mesh reference layer 230 wherein longitudinal mesh reference lines 233 have a smooth, curved transition 55 from a narrower portion 51 to a wider portion 52 of the longitudinal mesh reference lines 233. FIG. 8, by contrast, is a schematic plan view of the same mesh reference layer 230, except that the longitudinal mesh reference lines 233 have a stepped, ninety-degree transition 57 from the narrower portion 51 to the wider portion 52 of the longitudinal mesh reference lines 233.

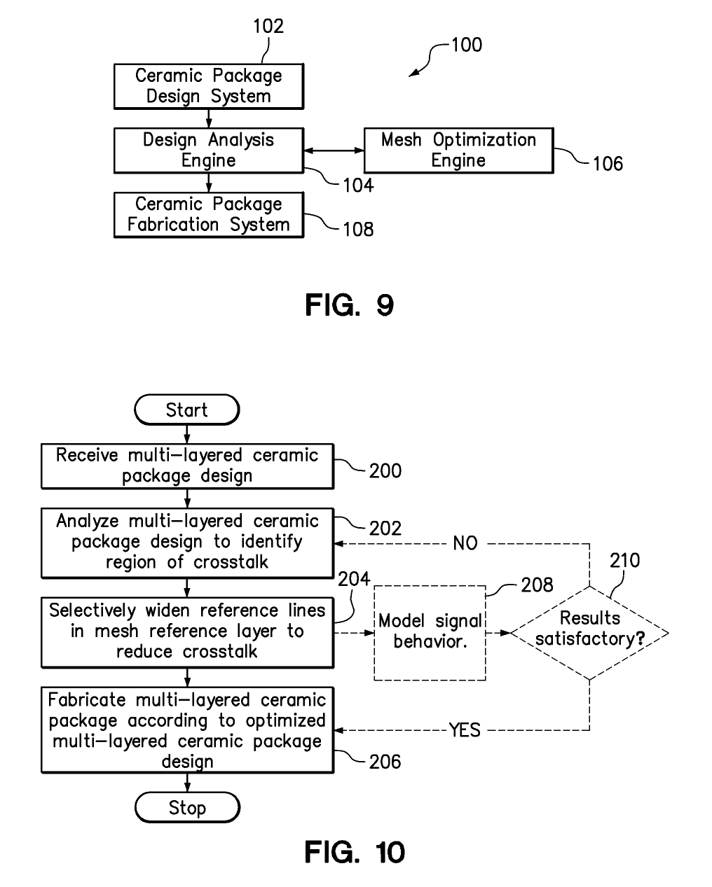

FIG. 9 is an exemplary block diagram of a system 100 for fabricating a multi-layered ceramic package in accordance with one embodiment of the invention. The system includes a ceramic package design system 102 coupled to a design analysis engine 104. Also coupled to the design analysis engine 104 is a mesh optimization engine 106 and a ceramic package fabrication system 108. The ceramic package design system 102 provides a design for the multi-layered ceramic package identifying the placement of signal lines, voltage and ground mesh reference layers, voltage and ground vias, and other elements of a ceramic package. The ceramic package design is electronically provided to the design analysis engine 104, which analyzes the design of the ceramic package to identify, among other things, regions of the ceramic package having a higher probability of signal cross-talk. Commercially-available full-wave solvers based on Maxwell's equations may be used for this analysis. The design analysis engine 104 may perform a multivariate analysis including such variables as signal speed, interface length and design margin, for example. The region(s) of highest probability for cross-talk may be selected for widening the mesh, since the limit for metal coverage may prevent all of the mesh from being uniformly widened throughout the ceramic package.

The identified regions of the mesh reference layers having the highest probability of signal cross-talk are provided for the mesh optimization engine 106, along with other ceramic package design data. The mesh optimization engine 106 selectively widens the mesh reference lines in the ceramic package design at the identified regions of the mesh reference layers.

After optimizing the mesh reference layers, the resulting ceramic package design is provided to the ceramic package fabrication system 108 for fabrication of the multi-layered ceramic package. Various ceramic package fabrication systems are known in the art outside of their particular application disclosed herein. Such ceramic package fabrication systems include, for example, high end servers, mainframes, etc. The ceramic package design, having been optimized according to an embodiment of the invention, may thereafter be manufactured using such a ceramic package fabrication system.

FIG. 10 is a flowchart outlining a method of optimizing a multi-layered ceramic package according to an embodiment of the invention. Step 200 involves receiving a multi-layered ceramic package design. The ceramic package design, as initially received in step 200, may be a conventional ceramic package design. A conventional design may have, for example, mesh reference layers with reference lines of standard, unvarying width. The received multi-layered ceramic package design is analyzed in step 202 to identify regions of probable cross-talk. For example, a full-wave solver such as EMITPKG, or another full-wave solver known in the art, may be used for performing such an analysis. In step 204, mesh reference lines are selectively widened at the identified regions of the mesh reference layers where the probability of cross-talk is the highest, without widening all of the mesh reference lines throughout the ceramic package. The resulting multi-layered ceramic package design having optimized mesh layers may then be provided to a fabrication system in step 206, which fabricates the shielded multi-layered ceramic package based on the shielded multi-layered ceramic package design.

An iterative process may be applied, as indicated in optional steps 208 and 210, wherein successive iterations of the ceramic package design are modeled as part of optimizing the mesh layers. In step 208, successive iterations of a ceramic package design, with mesh layers widened in step 204, may be modeled to observe the corresponding signal behavior. Conditional step 210 is to determine whether the results of the most recent ceramic package design iteration are satisfactory. A test for whether a particular iteration of the ceramic package design is satisfactory may be, for example, whether a target cross-talk value or a target cross-talk reduction has been achieved. Alternatively, a test for whether a particular iteration of the ceramic package design is satisfactory may be determining which of a plurality of iterations achieves the lowest amount of cross-talk.

As will be appreciated by one skilled in the art, the present invention may be embodied as a system, method or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product embodied in any tangible storage medium having computer-usable program code stored on the storage medium.

Any combination of one or more computer usable or computer readable storage medium(s) may be utilized. The computer-usable or computer-readable storage medium may be, for example but not limited to, an electronic, magnetic, electromagnetic, or semiconductor apparatus or device. More specific examples (a non-exhaustive list) of the computer-readable medium include: a portable computer diskette, a hard disk, random access memory (RAM), read-only memory (ROM), an erasable programmable read-only memory (EPROM or Flash memory), a portable compact disc read-only memory (CD-ROM), an optical storage device, or a magnetic storage device. The computer-usable or computer-readable storage medium could even be paper or another suitable medium upon which the program is printed, as the program can be electronically captured via, for instance, optical scanning of the paper or other medium, then compiled, interpreted, or otherwise processed in a suitable manner, if necessary, and then stored in a computer memory. In the context of this document, a computer-usable or computer-readable storage medium may be any storage medium that can contain or store the program for use by a computer. Computer usable program code contained on the computer-usable storage medium may be communicated by a propagated data signal, either in baseband or as part of a carrier wave. The computer usable program code may be transmitted from one storage medium to another storage medium using any appropriate transmission medium, including but not limited to wireless, wireline, optical fiber cable, RF, etc.

Computer program code for carrying out operations of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present invention is described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable storage medium that can direct a computer or other programmable data processing apparatus to function in a particular manner, such that the instructions stored in the computer-readable storage medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A multi-layered ceramic package, comprising:
a ceramic substrate;
a signal layer having a plurality of signal lines in the ceramic substrate; and
a mesh reference layer parallel to the signal layer, the mesh reference layer comprising a plurality of intersecting reference lines of varying reference-line width in the plane of the mesh reference layer.

2. The multi-layered ceramic package of claim 1, further comprising a first mesh region in the mesh reference layer having reference lines of a first reference-line width and a second mesh region in the mesh reference layer having reference lines of a second reference-line width greater than the first reference-line width.

3. The multi-layered ceramic package of claim 1, wherein the reference lines of the second reference-line width reduce at least one of near end or far end noise of one or more of the signal lines by at least fifty percent.

4. The multi-layered ceramic package of claim 1, wherein each reference line has a reference-line width that varies in a direction of a reference-line length.

5. The multi-layered ceramic package of claim 1, wherein a widened portion of each signal line is aligned with one of the reference lines and the widened portion is at least 10% wider than the aligned one of the reference lines.

6. The multi-layered ceramic package of claim 1, wherein the reference lines have a reference-line width that varies over a range of between 66 μm and 100 μm.

7. The multi-layered ceramic package of claim 6, wherein the signal lines are about 55 μm wide.

8. The multi-layered ceramic package of claim 1, further comprising:
a plurality of vias, each via extending from at least the signal layer to the mesh reference layer at an intersection between reference lines in the mesh reference layer.

9. The multi-layered ceramic package of claim 1, wherein the reference lines of the mesh reference layer comprise a ceramic material.

10. The multi-layered ceramic package of claim 1, wherein one or more of the reference lines each have a smooth, curved transition from a narrower portion to a wider portion.

11. The multi-layered ceramic package of claim 1, wherein one or more of the reference lines each have a stepped transition from a narrower portion to a wider portion.

12. The multi-layered ceramic package of claim 1, further comprising at least a second mesh reference layer, wherein the signal layer is sandwiched between the two mesh reference layers.

13. The multi-layered ceramic package of claim 12, wherein the mesh reference layer is a positive reference layer and the second mesh reference layer is a ground reference layer.

14. A system for fabricating a multi-layered ceramic package, comprising:
a multi-layered ceramic package design system configured to provide a multi-layered ceramic package design, wherein the multi-layered ceramic package design includes a signal layer having a plurality of signal lines and a mesh reference layer parallel to the signal layer and having a plurality of reference lines;
a mesh optimization engine configured to identify a region of probable signal cross-talk in the signal layer of the multi-layered ceramic package design and selectively increase the width of reference lines in the region of probable signal cross-talk; and
a ceramic package fabrication system that fabricates the multi-layered ceramic package based on the shielded multi-layered ceramic package design.

15. The system of claim 14, wherein the step of identifying a region of probable signal cross-talk in the signal layer of the multi-layered ceramic package design comprises identifying a region having signal lines within 60 μm apart.

16. The system of claim 14, wherein the step of identifying a region of probable signal cross-talk in the signal layer of the multi-layered ceramic package design comprises identifying a region wherein signals will be communicated at more than about two gigabits per second.

17. A computer program product including computer usable program code embodied on a computer usable storage medium for optimizing a multi-layer ceramic package, the computer program product including:
computer usable program code for receiving a multi-layered ceramic package design including a mesh reference layer having a plurality of uniform-width reference lines and a signal layer having a plurality of signal lines; and
computer usable program code for analyzing the signal layer of the multi-layered ceramic package design to identify a region of signal cross-talk; and
computer usable program code for selectively increasing the width of reference lines in the region of signal cross-talk.

18. The computer program product of claim 17, further comprising:
computer usable program code for selectively varying a reference-line width of one or more of the reference lines widths in a direction of a reference-line length.

19. The computer program product of claim 17, wherein the computer usable program code for selectively varying a reference-line width includes computer usable program code for providing a smooth transition from a narrower portion to a wider portion of a selected mesh reference line.

20. The computer program product of claim 17, wherein the computer usable program code for analyzing the signal layer of the multi-layered ceramic package design to identify a region of signal cross-talk in the signal layer comprises computer usable program code for identifying a region having signal lines spaced within 60 μm apart or having signal lines that will carry signals of a least 2 gigabits per second.
